(19) United States
(12) Patent Application Publication
(10) Pub. No.: US 2025/0364434 A1
(43) Pub. Date: Nov. 27, 2025

(54) STRESS CONTROL OF HIGH-DENSITY CARBON HARDMASK (CHM)

(71) Applicant: Tokyo Electron Limited, Tokyo (JP)

(72) Inventors: Jianping ZHAO, Austin, TX (US); Charles SCHLECHTE, Austin, TX (US); John CARROLL, Austin, TX (US); Peter Lowell George VENTZEK, Austin, TX (US)

(73) Assignee: Tokyo Electron Limited, Tokyo (JP)

(21) Appl. No.: 18/671,320

(22) Filed: May 22, 2024

(51) Int. Cl. H01L 23/00; H01L 21/033; H01L 21/66; H01L 21/67

(52) U.S. Cl. CPC H01L 23/562; H01L 21/0332; H01L 21/67288; H01L 22/12

(57) ABSTRACT

A method of microfabrication is provided. The method includes providing a wafer having a working surface. A correction layer recipe is executed to form a correction layer over the working surface. A carbon hardmask (CHM) layer is formed over the correction layer. The correction layer recipe is determined based on the CHM layer so that the wafer has a wafer bow value within a threshold after the correction layer and the CHM layer are formed.

### INCORPORATION BY REFERENCE

Aspects of the present disclosure are related to Applicant's U.S. Pat. No. 10,157,747 which is incorporated herein by reference in its entirety.

### FIELD OF THE INVENTION

This disclosure relates generally to semiconductor fabrication and more specifically to wafer shape control.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

### SUMMARY

The present disclosure relates to a method of microfabrication, an apparatus of executing the same, and a semiconductor device.

According to a first aspect of the disclosure, a method of microfabrication is provided. The method includes providing a wafer having a working surface. A correction layer recipe is executed to form a correction layer over the working surface. A carbon hardmask (CHM) layer is formed over the correction layer. The correction layer recipe is determined based on the CHM layer so that the wafer has a wafer bow value within a threshold after the correction layer and the CHM layer are formed.

In some embodiments, the CHM layer has a compressive stress, and the correction layer has a tensile stress.

In some embodiments, the tensile stress of the CHM layer is determined before executing the correction layer recipe.

In some embodiments, the correction layer recipe is determined based on the tensile stress of the CHM layer.

In some embodiments, the tensile stress is 60%-140% of the compressive stress.

In some embodiments, executing the correction layer recipe includes applying a pulsed direct current (DC) on the wafer.

In some embodiments, the pulsed DC is pulsed between an ON state and an OFF state.

In some embodiments, the correction layer recipe includes at least one selected from the group consisting of a pulsed DC voltage, a pulsed DC frequency, a duty cycle, an RF source power, a pressure, a temperature, a correction layer material, a layer thickness and a low pass filter.

In some embodiments, the CHM layer and the correction layer both include carbon material. The CHM layer has a higher density than the correction layer.

In some embodiments, the method further includes switching from the correction layer recipe to a CHM layer recipe in a chamber without moving the wafer out of the chamber. The CHM layer and the correction layer are both formed in the chamber.

In some embodiments, the CHM layer has a first density of 1.3-2.0 g/cm³, and the correction layer has a second density of 0.8-1.3 g/cm³.

In some embodiments, the CHM layer is thicker than the correction layer.

In some embodiments, a layer stack is formed by repeating at least one more time forming the correction layer and forming the CHM layer. The layer stack alternates between the correction layer and the CHM layer.

In some embodiments, the correction layer includes amorphous carbon, non-amorphous carbon or silicon nitride.

In some embodiments, one or more layers of the wafer are etched using the CHM layer as an etching mask. The one or more layers are positioned between the working surface and the correction layer.

In some embodiments, the one or more layers include a layer stack alternating between silicon nitride and silicon oxide.

According to a second aspect of the disclosure, an apparatus is provided. The apparatus includes a controller including a processor that is programmed to provide a wafer having a working surface. A correction layer recipe is executed to form a correction layer over the working surface. A carbon hardmask (CHM) layer is formed over the correction layer. The correction layer recipe is determined based on the CHM layer so that the wafer has a wafer bow value within a threshold after the correction layer and the CHM layer are formed.

According to a third aspect of the disclosure, a semiconductor device is provided. The semiconductor device includes a substrate having a working surface. A first layer stack is positioned over the working surface and alternates between a first material and a second material. A second layer stack is positioned over the first layer stack and alternates between a correction layer and a carbon hardmask (CHM) layer.

In some embodiments, the first material includes silicon oxide. The second material includes silicon nitride or polysilicon. The CHM layer includes high-density carbon. The correction layer includes low-density carbon.

In some embodiments, the high-density carbon has a first density of 1.3-2.0 g/cm³, and the low-density carbon has a second density of 0.8-1.3 g/cm³.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1A shows a vertical cross-sectional view of a semiconductor device in accordance with one embodiment of the present disclosure.

FIG. 1B shows a vertical cross-sectional view of another semiconductor device in accordance with another embodiment of the present disclosure.

FIG. 2 shows schematic views of wafer shapes under different stresses in accordance with some embodiments of the present disclosure.

FIG. 3 shows a block diagram of a process for manufacturing a semiconductor device, in accordance with some embodiments of the present disclosure.

FIGS. 4A, 4B, 4C and 4D show vertical cross-sectional views of a semiconductor device at various intermediate steps of manufacturing, in accordance with some embodiments of the present disclosure.

FIG. 5 shows a schematic of pulsed bias power in accordance with one embodiment of the present disclosure.

FIG. 6 shows a schematic of a low pass filter in accordance with one embodiment of the present disclosure.

FIGS. 7A, 7B and 7C show vertical cross-sectional views of semiconductor devices.

FIG. 8 shows a plot of film stress versus film density in accordance with one embodiment of the present disclosure.

FIG. 9 shows a flow chart of a process for manufacturing a semiconductor device, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

As noted in the Background, semiconductor fabrication development now incorporates techniques such as advanced patterning and 3D device construction to reduce feature size and increase device density. The implementation of these techniques, however, has created new challenges for successful microfabrication. These new fabrication approaches include the creation of multiple layers or films of various materials on the wafer surface. Each layer, however, adds additional stress to the surface of the wafer. As the layers or films build up, the induced stress distorts the flatness of the wafer. This distortion has been shown to reduce the size uniformity of critical features across the surface of the wafer.

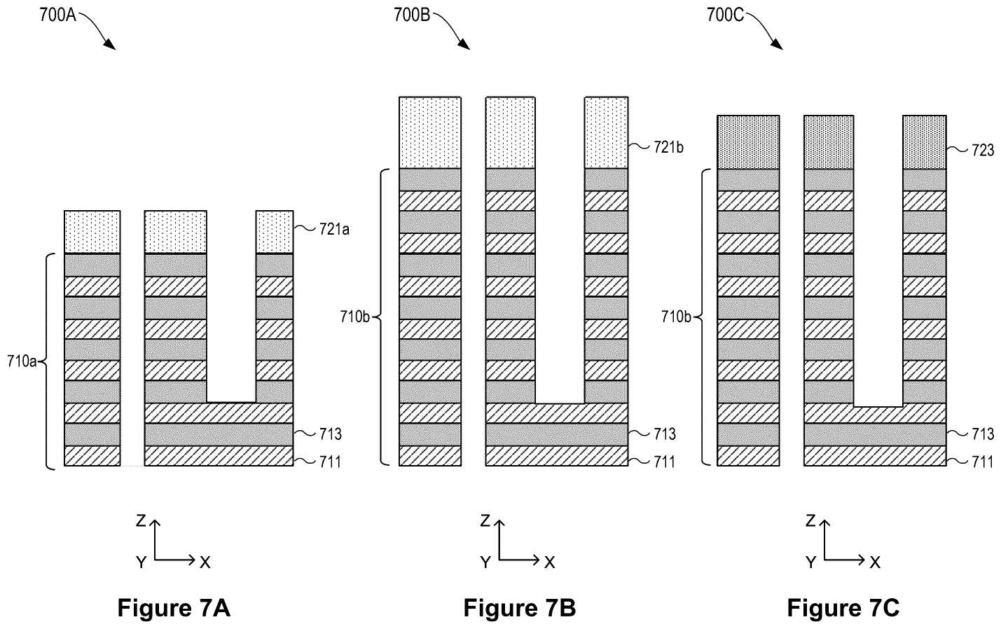

FIG. 7A shows a wafer 700A including a first layer stack 710a alternating between a first material 711 (e.g. silicon oxide) and a second material 713 (e.g. silicon nitride or polysilicon). In a typical three-dimensional (3D) NAND memory device, the first layer stack 710a can include sixty-four to a hundred and twenty-eight layers. A first etching mask 721a is formed over the first layer stack 710a for high-aspect-ratio etching purposes. FIG. 7B shows a wafer 700B including a second layer stack 710b alternating between the first material 711 and the second material 713. As shown, the second layer stack 701b has more layers than the first layer stack 710a. As a result, a second etching mask 721b formed over the second layer stack 710b is thicker than the first etching mask 721a in order to accommodate etching of an even higher aspect ratio. Nevertheless, a thicker etching mask can reduce the effective aspect ratio of the etch/patterning stack. Therefore, a third etching mask 723 having a higher density and thus a smaller thickness is desired over the second layer stack 710b as illustrated in FIG. 7C.

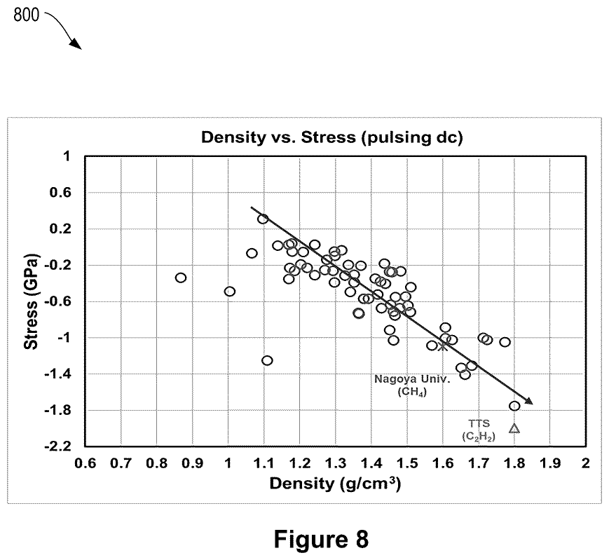

Particularly, carbon hardmask (CHM) can be used as the third etching mask 723 for 3D NAND memory technology in FIGS. 7A-7C as well as hard anti-reflective coating (HARC). High density CHM will relieve the etch burden for the high aspect ratio etching process. However, CHM has fallen short of industrial expectations due to ever-increasing vertical dimensions in HARC and 3D NAND for advanced patterning. CHM thickness should not be scaled as feature scaling due to increased effective aspect ratio caused by CHM scaling. High etch resistance requires films of high density. However, high compressive stress is often inherent to high density, especially for plasma enhanced chemical vapor deposition (PECVD) processes at low temperature using radio frequency (RF) or microwave (MW) plasma with or without direct current (DC) pulsing. As can be seen in a graph 800 of FIG. 8, the stress of CHM generally increases with density in an approximately or roughly linear relationship. Without using post thermal treatment or plasma treatment, it is impossible to break the high-density-and-high-stress trend.

As discussed earlier, when the layers build up in a semiconductor device, the induced stress distorts the flatness of the wafer. To make things worse, the stress of high-density CHM as an etching mask can further exacerbate the distortion problem. This distortion can result in overlay errors and challenges. Various fabrication process steps can cause expansion and/or contraction of the substrate, resulting in a warped or bowed substrate. For example, during exposure a substrate is heated locally due to the energy transferred to the substrate from an exposure beam. Substrates are also heated during annealing processes. This heating causes the substrate to expand. If the substrate expansion is unchecked, the expansion exceeds overlay error requirements. Moreover, if the clamping force between the substrate and the substrate chuck is insufficient to prevent substrate expansion, then the substrate can slip on the substrate chuck and larger substrate expansion will occur, resulting in larger overlay errors. Slipping can be more pronounced in some processes such as extreme ultraviolet (EUV) systems, because the environment surrounding the substrate during exposure is a vacuum. Thus, vacuum clamping is not always possible, and the weaker electrostatic clamping must be used in lieu of a vacuum clamp.

Conventional techniques used to address substrate bow and uneven curvature on partially processed substrates often focus on chucking techniques to chuck (or clamp/suck) a substrate to a substrate holder to flatten the curvature. With relatively significant bowing, however, it can be very difficult or impossible to accurately flatten a substrate by chucking alone. Efforts have also been made to form a correction film on the backside of a wafer (relative to a working surface of the wafer) to correct substrate bow and improve overlay, for example as disclosed in Applicant's U.S. Pat. No. 10,157,747.

Techniques herein utilize a high tensile stress layer as an interface between the substrate and carbon hardmask (CHM) to mitigate high compressive stress of a high density CHM film. By controlling the tensile stress of the interface layer, the final stress amplitude and direction can be controlled for various applications. The interface layer can for example be an amorphous carbon layer or a non-amorphous carbon layer which can be ashed. As a result, high density CHM can be achieved with a low overall compressive stress, which releases the burden of extra thermal or plasma treatment for stress reduction. Such low stress can enable pattern transfer at high resolution with improved overlay control and patterning fidelity.

According to aspects of the disclosure, CHM having high density and high stress can be formed by PECVD using RF plasma and pulsed DC. The interface tensile stress layer can be inserted anytime during CHM deposition, forming a single “sandwich” structure or multilayer structure with alternating tensile and compressive stress layers, to control the final stress of the wafer. A proper ion energy window can be critical for a high density film for high etch resistivity. The tensile or compressive stress can be adjusted by deposition conditions such as pulsed DC voltage, duty cycle, pulsed frequency, RF power, pressure, etc. Therefore, post thermal treatment or plasma treatment to reduce stress may not be necessary.

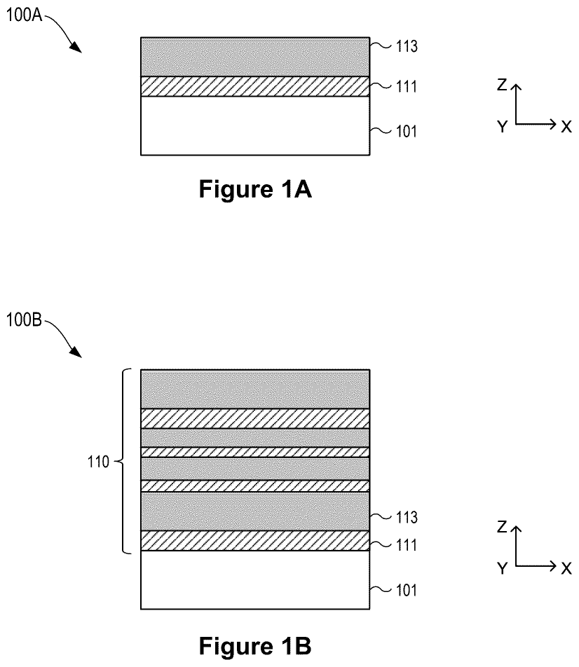

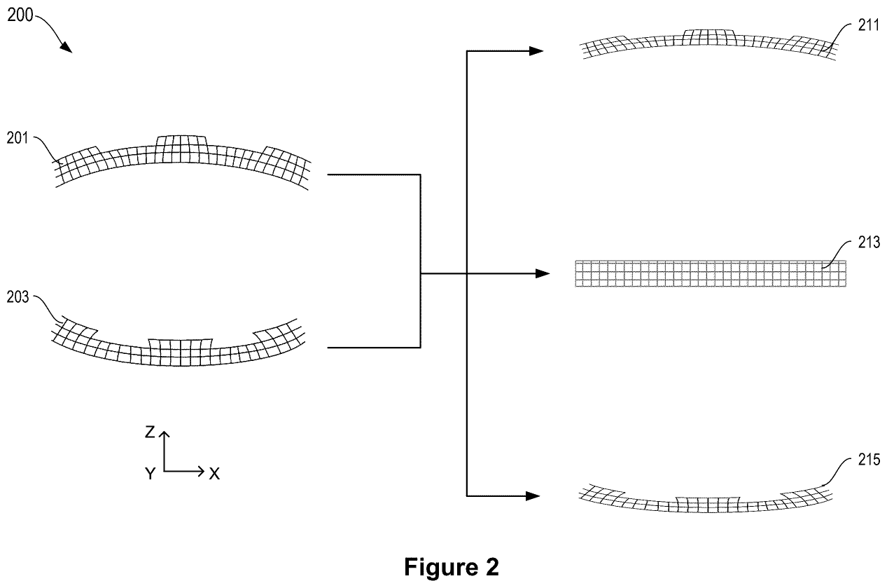

FIG. 1A shows a vertical cross-sectional view of a semiconductor device 100A, and FIG. 2 shows a schematic 200 of wafer shapes under different stresses, in accordance with some embodiments of the present disclosure. As shown, the semiconductor device 100A includes a substrate 101, a correction layer 111 over the substrate 101 and a carbon hardmask (CHM) layer 113 over the correction layer 111.

The CHM layer 113 can be a high density CHM layer and thus have a high compressive stress that may lead to a compressive wafer shape 201. The CHM layer 113 can have a first density of 1.3-2.0 g/cm³, e.g. 1.3 g/cm³, 1.4 g/cm³, 1.5 g/cm³, 1.6 g/cm³, 1.7 g/cm³, 1.8 g/cm³, 1.9 g/cm³, 2.0 g/cm³ or any values therebetween. As discussed earlier and shown in FIG. 8, the higher the first density is, the higher compressive stress the CHM layer 113 tend to have. The CHM layer 113 can have a compressive stress of 0.2-2.0 GPa, e.g. 0.2 GPa, 0.5 GPa, 1.0 GPa, 1.5 GPa, 2.0 GPa or any values therebetween.

Therefore, to avoid undesirable wafer bowing, the correction layer 111 can have a high tensile stress to correct an overall stress of the semiconductor device 100A. That is, the correction layer 111 alone can lead to a tensile wafer shape 203 so the tensile stress of the correction layer 111 can mitigate the compressive stress of the CHM layer 113 to some extent. The correction layer 111 can have a tensile stress of 0.2-2.0 GPa, e.g. 0.2 GPa, 0.5 GPa, 1.0 GPa, 1.5 GPa, 2.0 GPa or any values therebetween.

By controlling the tensile stress of the correction layer 111 and/or the compressive stress of the CHM layer 113, the semiconductor device 100A may have a compressive wafer surface 211 whose curvature is mitigated compared with the compressive wafer shape 201, a flat wafer surface 213, or a tensile wafer surface 215 whose curvature is mitigated compared with the tensile wafer shape 203. Depending on specific applications, the compressive wafer surface 211, the flat wafer surface 213 and the tensile wafer surface 215 may all be acceptable within a wafer bow value threshold.

Note that the CHM layer 113 can be used as an etching mask while the correction layer 111 can prevent undesirable wafer bowing. Therefore, the CHM layer 113 is preferably thicker than the correction layer 111. A thickness of the correction layer 111 can be 10%-90% (e.g. 10%, 20%, 30%, 40%, 50%, 70%, 90% or any values therebetween) of a thickness of the CHM layer 113. Additionally, the tensile stress of the correction layer 111 can be close to or higher than the compressive stress of the CHM layer 113 in absolute values. For example, the tensile stress of the correction layer 111 can be 60%-140% (e.g. 60%, 80%, 90%, 100%, 110%, 120%, 140% or any values therebetween) of the compressive stress of the CHM layer 113.

In some embodiments, the correction layer 111 is a low density CHM layer and has a second density that is smaller than the first density. The second density can be 0.8-1.3 g/cm³, e.g. 0.8 g/cm³, 0.9 g/cm³, 1.0 g/cm³, 1.1 g/cm³, 1.2 g/cm³, 1.3 g/cm³ or any values therebetween. In one embodiment, the correction layer 111 includes a material which can be selectively removed relative to layers underneath. For instance, the correction layer 111 can include amorphous carbon or non-amorphous carbon, either of which can be ashed during removal. In another embodiment, the correction layer 111 includes a material that does not need to be removed and thus may remain as part of the semiconductor device 100A. For instance, the correction layer 111 can include silicon nitride.

In the example of FIG. 1A, the correction layer 111 is in direct contact with both the CHM layer 113 and the substrate 101. It should be understood that in other examples (not shown), the semiconductor device 100A may include one or more layers between the correction layer 111 and the CHM layer 113 and/or include one or more layers between the correction layer 111 and the substrate 101. Particularly for 3D NAND applications, the semiconductor device 100A may include the first layer stack 710a, the second layer stack 710b or the like, between the correction layer 111 and the substrate 101. In other words, the CHM layer 113 can be used as an etching mask for an ONON (oxide/nitride/oxide/nitride) or OPOP (oxide/polysilicon/oxide/polysilicon) stack to manufacture a 3D NAND device.

FIG. 1B shows a vertical cross-sectional view of a semiconductor device 100B in accordance with another embodiment of the present disclosure. The embodiment of the semiconductor device 100B is similar to the embodiment of the semiconductor device 100A. Similar or identical components are labeled with similar or identical numerals unless specified otherwise. Descriptions have been provided above and will be omitted for simplicity purposes. Herein, the semiconductor device 100B includes a layer stack 110 alternating between the correction layer 111 and the CHM layer 113. Thicknesses, densities and/or stresses of the correction layer 111 and the CHM layer 113 may vary within the layer stack 110.

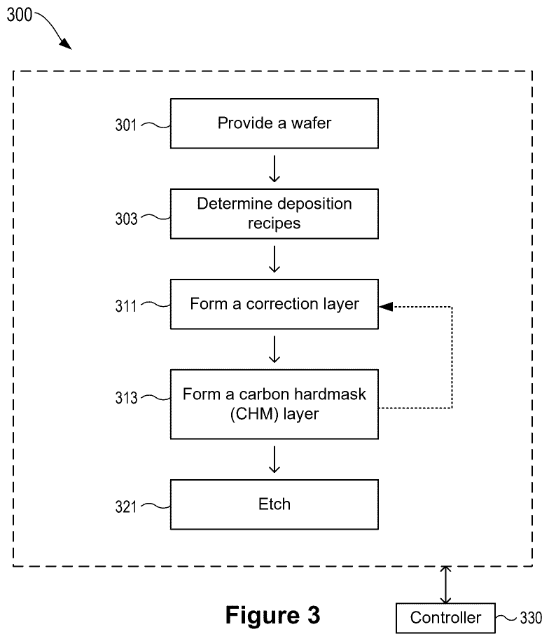

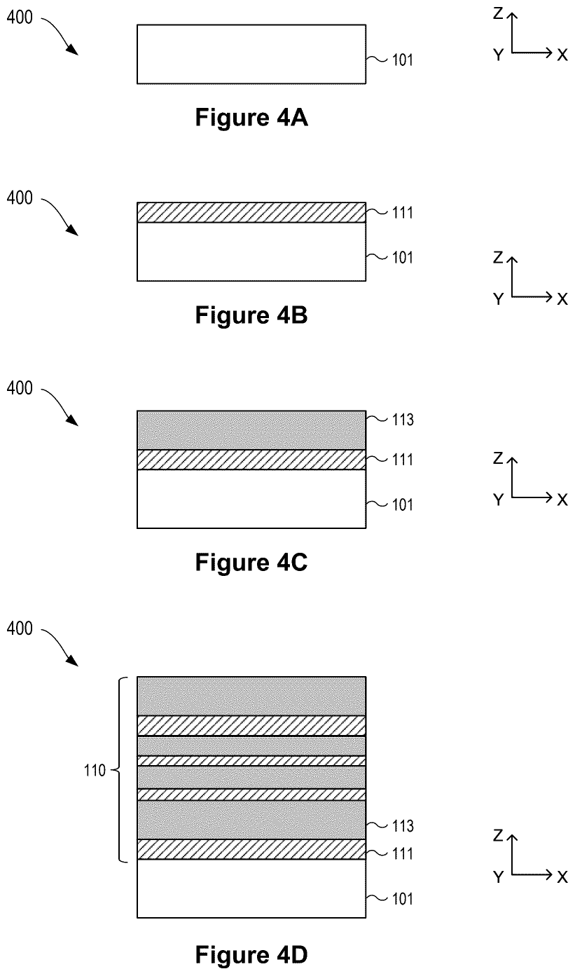

FIG. 3 shows a block diagram of a process 300 for manufacturing a semiconductor device (e.g. 100A, 100B or the like), and FIGS. 4A, 4B, 4C and 4D show vertical cross-sectional views of a wafer 400 at various intermediate steps of manufacturing, in accordance with some embodiments of the present disclosure. The process 300 can be executed in a system including various modules such as one or more film deposition modules, one or more etching modules, and/or the like. Some examples of the system are disclosed in Applicant's U.S. Pat. No. 10,157,747 which is incorporated herein by reference in its entirety.

In block 301, a wafer is provided. For example in FIG. 4A, a wafer 400 is provided. The wafer 400 can include the substrate 101 and optionally one or more layers such as the first layer stack 710a formed on the substrate 101.

In block 303, deposition recipes are determined before a correction layer (e.g. 111) and a carbon hardmask (CHM) layer (e.g. 113) are formed. Material type, density and thickness of the CHM layer can be determined based on specific etching applications. Therefore, a compressive stress of the CHM layer can be determined. Accordingly, material type, density and thickness of the correction layer can be determined so that a tensile stress of correction layer and the compressive stress of the CHM layer will together lead to a wafer bow value within a threshold.

In a non-limiting example, a calibration can be done in advance. A series of CHM layers having various densities and formed under various experimental conditions can be deposited on dummy substrates, and corresponding compressive stresses can be measured. A mathematical model, linear or non-linear, can be built by regression to describe compressive stress as a function of density and/or experimental conditions. The mathematical model can thus be used to estimate or predict the compressive stress of the CHM layer. Similarly, another mathematical model can be built to estimate or predict the tensile stress of the correction layer based on material type, material density and/or experimental conditions.

As a result, a correction layer recipe and a CHM layer recipe can respectively be determined for the correction layer and the CHM layer based on respective material type, density and/or thickness. The correction layer recipe and the CHM layer recipe may each include information such as a pulsed DC voltage, a pulsed DC frequency, a duty cycle, an RF source power, a pressure, a temperature, a layer material, a layer thickness and/or the like.

In block 311, the correction layer recipe is executed to form the correction layer. For example in FIG. 4B, the correction layer 111 is formed over the substrate 101.

In block 313, the CHM layer recipe is executed to form the CHM layer. In some embodiments (not shown), the CHM layer recipe may be determined or modified based on metrology data of the correction layer between block 311 and block 313. For example in FIG. 4C, the CHM layer 113 is formed over the correction layer 111. As a result, the wafer 400 can become the semiconductor device 100A.

In one embodiment, the correction layer and the CHM layer each are formed once before used as an etching mask in an etching process in block 321. In another embodiment, the correction layer and the CHM layer each are formed more than once before used as an etching mask in block 321. That is, the process 300 may return to block 311 after block 313 is executed. The process 300 can thus repeatedly form the correction layer and the CHM layer for any number of cycles. Accordingly, a plurality of correction layer recipes and a plurality of CHM layer recipes can be determined in block 303 or determined/modified after collecting metrology data after each film deposition during a plurality of cycles. For example in FIG. 4D, the layer stack 110 is formed over the substrate 101. As a result, the wafer 400 can become the semiconductor device 100B.

In some embodiments, the correction layer and the CHM layer respectively include high density CHM and low density CHM. Accordingly, the correction layer and the CHM layer can be formed in a common chamber in a continuous deposition process. That is to say, the common chamber can switch from the correction layer recipe to the CHM layer recipe without moving the wafer out of the common chamber. The common chamber can also alternate between the correction layer recipe and the CHM layer recipe without moving the wafer out of the common chamber.

Further, a controller 330 may optionally be included in the example of FIG. 3. Components of a corresponding plasma tool can be connected to and controlled by the controller 330 that may optionally be connected to a corresponding memory storage unit and user interface (all not shown). Various plasma-processing operations can be executed via the user interface, and various plasma processing recipes and operations can be stored in a storage unit. Accordingly, a given substrate can be processed within a plasma chamber with various microfabrication techniques.

It will be recognized that the controller 330 may be coupled to various components of the corresponding plasma tool to receive inputs from and provide outputs to the components. For example, the controller 330 can be configured to receive data from the corresponding plasma tool. The controller 330 can also be configured to adjust knobs and control settings for the corresponding plasma tool. Of course the adjustments can be manually made as well.

It will also be recognized that the controller 330 may be coupled to various components of the process 300 to receive inputs from and provide outputs to the components. The controller 330 can be configured to implement blocks 301, 303, 311, 313 and/or 321. For example, the controller 330 can receive and load the wafer, determine and execute the deposition recipes, execute an etching process, and/or the like. Of course, one or more functions of the controller 330 can also be manually accomplished.

The controller 330 can be implemented in a wide variety of manners. In one example, the controller 330 is a computer. In another example, the controller 330 includes one or more programmable integrated circuits that are programmed to provide the functionality described herein. For example, one or more processors (e.g. microprocessor, microcontroller, central processing unit, etc.), programmable logic devices (e.g. complex programmable logic device (CPLD)), field programmable gate array (FPGA), etc.), and/or other programmable integrated circuits can be programmed with software or other programming instructions to implement the functionality of a proscribed plasma process recipe. It is further noted that the software or other programming instructions can be stored in one or more non-transitory computer-readable mediums (e.g. memory storage devices, FLASH memory, DRAM memory, reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations could also be implemented.

Additionally, a controller 140 in the aforementioned Applicant's U.S. Pat. No. 10,157,747 can be included as part of the controller 330 herein. Descriptions of the controller 140 are provided in Applicant's U.S. Pat. No. 10,157,747 and will be omitted herein for simplicity purposes.

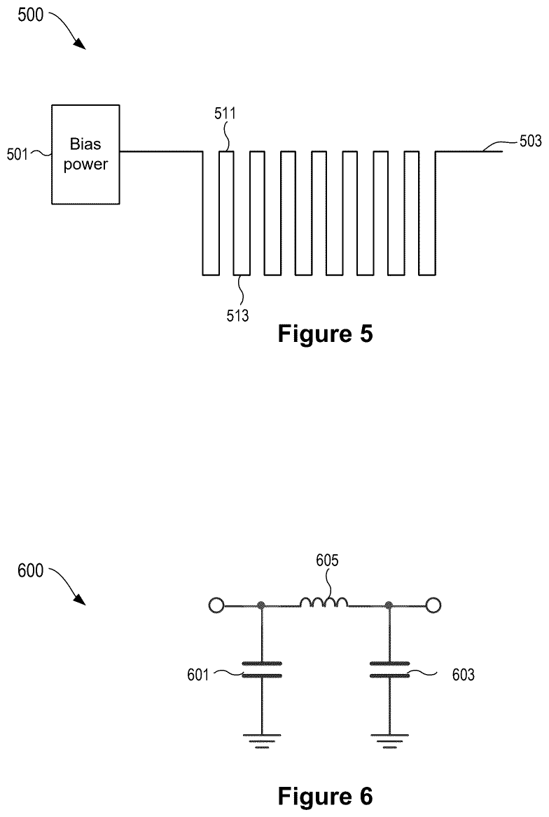

The density and stress of CHM can be controlled by film deposition conditions such as a bias power applied on the wafer 400. FIG. 5 shows a schematic 500 of pulsed bias power in accordance with one embodiment of the present disclosure. As shown, a bias power 501 is represented by line 503. The bias power 501 is pulsed between an OFF state 511 and an ON state 513. The OFF state 511 can correspond to a first bias voltage of 0-5 V, e.g. 0V, 1V, 2V, 3V, 4V, 5V or any values therebetween. The ON state 513 can correspond to a second bias voltage that is larger than the first bias voltage in absolute values and is otherwise not particularly limited. The bias power 501 can have a duty cycle of 10%-90%, e.g. 10%, 30%, 50%, 70%, 90% or any values therebetween.

Further, inventors discovered that design of a low pass filter can have significant effect on stress control while optimizing other conditions such as dilution gases. FIG. 6 shows a schematic of a low pass filter 600 in accordance with some embodiments of the present disclosure. The low pass filter 600 can include a first capacitor 601, a second capacitor 603 and a conductor 605.

In one embodiment, the first capacitor 601 has an electrical capacitance of 5 nF. The second capacitor 603 has an electrical capacitance of 5 nF. The conductor 605 has an electrical inductance of 1.2 μH. When the low pass filter 600 is used for forming a low density CHM as the correction layer in block 311, the low density CHM can have a density of 1.23 g/cm³ and a tensile stress of 1.40 GPa.

In another embodiment, the first capacitor 601 has an electrical capacitance of 55 pF. The second capacitor 603 has an electrical capacitance of 45 pF. The conductor 605 has an electrical inductance of 100 μH. When the low pass filter 600 is used for forming a high density CHM as the CHM layer in block 313, the high density CHM can have a density of 1.65 g/cm³ and a compressive stress of 1.33 GPa.

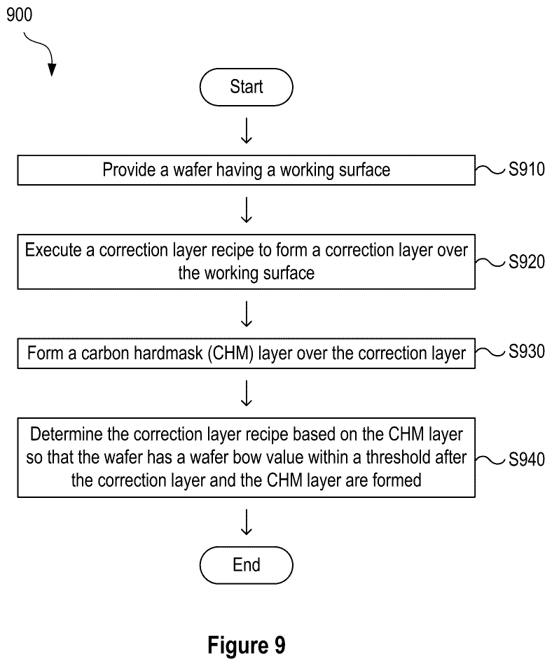

FIG. 9 shows a flow chart of a process 900 for manufacturing a semiconductor device (e.g. 100A, 100B and the like), in accordance with some embodiments of the present disclosure. At step S910, a wafer having a working surface is provided. At step S920, a correction layer recipe is executed to form a correction layer over the working surface. At step S930, a carbon hardmask (CHM) layer is formed over the correction layer. At step S940, the correction layer recipe is determined based on the CHM layer so that the wafer has a wafer bow value within a threshold after the correction layer and the CHM layer are formed.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of microfabrication, the method comprising:
providing a wafer having a working surface;
executing a correction layer recipe to form a correction layer over the working surface;
forming a carbon hardmask (CHM) layer over the correction layer; and
determining the correction layer recipe based on the CHM layer so that the wafer has a wafer bow value within a threshold after the correction layer and the CHM layer are formed.

2. The method of claim 1, wherein:
the CHM layer has a compressive stress, and
the correction layer has a tensile stress.

3. The method of claim 2, further comprising:
determining the tensile stress of the CHM layer before executing the correction layer recipe.

4. The method of claim 3, further comprising:
determining the correction layer recipe based on the tensile stress of the CHM layer.

5. The method of claim 2, wherein:
the tensile stress is 60%-140% of the compressive stress.

6. The method of claim 1, wherein:
executing the correction layer recipe comprises applying a pulsed direct current (DC) on the wafer.

7. The method of claim 6, wherein:
the pulsed DC is pulsed between an ON state and an OFF state.

8. The method of claim 6, wherein:
the correction layer recipe includes at least one selected from the group consisting of a pulsed DC voltage, a pulsed DC frequency, a duty cycle, an RF source power, a pressure, a temperature, a correction layer material, a layer thickness and a low pass filter.

9. The method of claim 1, wherein:
the CHM layer and the correction layer both comprise carbon material, and
the CHM layer has a higher density than the correction layer.

10. The method of claim 9, further comprising:
switching from the correction layer recipe to a CHM layer recipe in a chamber without moving the wafer out of the chamber, wherein the CHM layer and the correction layer are both formed in the chamber.

11. The method of claim 9, wherein:
the CHM layer has a first density of 1.3-2.0 g/cm³, and
the correction layer has a second density of 0.8-1.3 g/cm³.

12. The method of claim 1, wherein:
the CHM layer is thicker than the correction layer.

13. The method of claim 1, further comprising:
forming a layer stack by repeating at least one more time forming the correction layer and forming the CHM layer, the layer stack alternating between the correction layer and the CHM layer.

14. The method of claim 1, wherein:
the correction layer comprises amorphous carbon, non-amorphous carbon or silicon nitride.

15. The method of claim 1, further comprising:
etching one or more layers of the wafer using the CHM layer as an etching mask, wherein the one or more layers are positioned between the working surface and the correction layer.

16. The method of claim 15, wherein:
the one or more layers comprise a layer stack alternating between silicon nitride and silicon oxide.

17. An apparatus, comprising a controller including a processor that is programmed to:
provide a wafer having a working surface;
execute a correction layer recipe to form a correction layer over the working surface;
form a carbon hardmask (CHM) layer over the correction layer; and
determine the correction layer recipe based on the CHM layer so that the wafer has a wafer bow value within a threshold after the correction layer and the CHM layer are formed.

18. A semiconductor device, comprising:
a substrate having a working surface;
a first layer stack positioned over the working surface and alternating between a first material and a second material; and
a second layer stack positioned over the first layer stack and alternating between a correction layer and a carbon hardmask (CHM) layer.

19. The semiconductor device of claim 18, wherein:
the first material comprises silicon oxide,
the second material comprises silicon nitride or polysilicon,
the CHM layer comprises high-density carbon, and
the correction layer comprises low-density carbon.

20. The semiconductor device of claim 19, wherein:
the high-density carbon has a first density of 1.3-2.0 g/cm³, and
the low-density carbon has a second density of 0.8-1.3 g/cm³.
